(19) United States
(12) Patent Application Publication
(10) Pub. No.: US 2025/0374672 A1
(43) Pub. Date: Dec. 4, 2025

(54) SEMICONDUCTOR DEVICES WITH VERTICALLY INTEGRATED TRANSISTORS THAT UTILIZE STACKED NANOSHEETS AS CHANNEL REGIONS

(71) Applicant: Samsung Electronics Co., Ltd., Suwon-si (KR)

(72) Inventors: Jisoo Park, Suwon-si (KR); Junghan Lee, Suwon-si (KR); Byungsung Kim, Suwon-si (KR); Kwanyoung Chun, Suwon-si (KR)

(21) Appl. No.: 19/201,183

(22) Filed: May 7, 2025

(30) Foreign Application Priority Data
Jun. 3, 2024 (KR) 10-2024-0072271

(51) Int. Cl. H10D 84/90

(52) U.S. Cl. CPC H10D 84/975; H10D 84/953

(57) ABSTRACT

A semiconductor device includes a first source/drain, a second source/drain, a first nanosheet, a second nanosheet, and interconnect, which is configured to electrically connect the first source/drain to the second source/drain, and contacts the first and second nanosheets. The interconnect includes an enclosure, a first side via region extending inside the enclosure and electrically connected to the first source/drain, a second side via region extending inside the enclosure and electrically connected to the second source/drain, and a side metal region, which extends inside the enclosure and is electrically connected to the first side via region and the second side via region.

### REFERENCE TO PRIORITY APPLICATION

This application claims priority to Korean Patent Application No. 10-2024-0072271, filed Jun. 3, 2024, the disclosure of which is hereby incorporated herein by reference.

### FIELD OF THE INVENTION

The present disclosure relates to semiconductor devices and, more particularly, to semiconductor device including vertically integrated transistors therein.

### BACKGROUND

A field effect transistor that applies voltage to a gate electrode and generates a channel through which electrons or holes flow in response to an electric field is being developed.

### SUMMARY

Embodiments provide a semiconductor device having a reduced area and increased performance.

According to an aspect, there is provided a semiconductor device including a first source/drain, a second source/drain, a first nanosheet, a second nanosheet, and an interconnect connecting the first source/drain to the second source/drain. The interconnect includes an enclosure, a first side via region located inside the enclosure and connected to the first source/drain, a second side via region located inside the enclosure and connected to the second source/drain, and a side metal region located inside the enclosure and connected to the first side via region and the second side via region, in which the first nanosheet and the second nanosheet contact the interconnect. This interconnect may be configured to separate each of the first nanosheet and the second nanosheet. In some embodiments, the side metal region may not extend beyond the first nanosheet or the second nanosheet in a height direction of the side metal region.

In addition, an inclination of the first side via region or the second side via region may be substantially the same as an inclination of the side metal region, in one cross-section of the interconnect. In addition, the interconnect may further include a first side metal recess in contact with the first side via region and the side metal region. The first side via region and the first side metal recess may be arranged along the side metal region. An inclination of the first side via region may be substantially the same as an inclination of the first side metal recess, in one cross-section of the interconnect. An inclination of the first side via region may be different from an inclination of the first side metal recess, in one cross-section of the interconnect. The interconnect may further include a second side metal recess in contact with the second side via region and the side metal region.

The semiconductor device may further include a plurality of first nanosheets (e.g., semiconductor nanosheets) and a plurality of second nanosheets, and the side metal region may have the minimum cutting length that is substantially the same as or less than a distance between adjacent first nanosheets among the plurality of first nanosheets or a distance between adjacent second nanosheets among the plurality of second nanosheets.

According to another aspect, there is provided a method of manufacturing a semiconductor device including forming a first source/drain, a second source/drain, an interconnect including an enclosure, and a first nanosheet and a second nanosheet in contact with the enclosure, in which the forming of the interconnect includes forming a side metal region as at least a portion of a side metal inside the enclosure. The forming of the interconnect may include forming at least one of a first side via region connected to the first source/drain or a second side via region connected to the second source/drain by recessing a portion of the side metal. The method may further include forming a first contact metal connecting the first source/drain to the first side via region, and forming a second contact metal connecting the second source/drain to the second side via region.

An inclination of the first side via region or the second side via region may be substantially the same as an inclination of the side metal region, in one cross-section of the interconnect. An inclination of a side metal recess formed by recessing a portion of the side metal may be substantially the same as an inclination of the first side via region or the second side via region, in one cross-section of the interconnect. An inclination of a side metal recess formed by recessing a portion of the side metal may be different from an inclination of the first side via region or the second side via region, in one cross-section of the interconnect. The forming of the side metal region may include cutting, as a unit, a metal having a minimum cutting length that is substantially the same as or less than a distance between adjacent first nanosheets or a distance between adjacent second nanosheets.

The method may further include forming a first contact metal connected to the first source/drain. The method may further include forming a second contact metal connected to the second source/drain.

Additional aspects of embodiments will be set forth in part in the description which follows and, in part, will be apparent from the description, or may be learned by practice of the disclosure. According to embodiments, the difficulty of manufacturing a semiconductor device may be reduced by reducing an etching aspect ratio and securing a pattern line width size of a side metal of an interconnect.

According to embodiments, a distance between a gate cut and a nanosheet may be reduced, a height of a semiconductor device may be reduced, or a width of a nanosheet may increase. According to embodiments, the performance of a semiconductor device may be improved by reducing capacitance between a gate cut and a gate. The effects of the semiconductor device according to embodiments are not limited to the above-mentioned effects, and other unmentioned effects can be clearly understood from the following description by one of ordinary skill in the art.

### BRIEF DESCRIPTION OF THE DRAWINGS

The foregoing and other aspects, features, and advantages of embodiments in the disclosure will become apparent from the following detailed description with reference to the accompanying drawings.

FIG. 1 is a perspective view of a semiconductor device;

FIG. 2 is a plan view of a semiconductor device;

FIG. 3 is a bottom view of a semiconductor device;

FIG. 4 is a cross-sectional view taken along the line 4-4 of the semiconductor device of FIG. 2;

FIG. 5 is a cross-sectional view taken along the line 5-5 of the semiconductor device of FIG. 2;

FIG. 6 is a cross-sectional view taken along the line 6-6 of the semiconductor device of FIG. 2;

FIGS. 7 to 15 are diagrams illustrating a method of manufacturing a semiconductor device, where:

FIG. 7 illustrates the formation of a first gate electrode, a second gate electrode, and an interconnect such that a plurality of first nanosheets and a plurality of second nanosheets contact the interconnect;

FIG. 8 illustrates the formation of a contact metal connected to a first source/drain;

FIG. 9 illustrates the formation of a first pre-side metal in an interconnect;

FIG. 10 illustrates the formation of a first side via region and a side metal region from a first pre-side metal in an interconnect;

FIG. 11 is a cross-sectional view taken along the line 11-11 of FIG. 10;

FIG. 12 illustrates the formation of a contact metal connecting a first pre-side metal to a first source/drain;

FIG. 13 illustrates the formation of a second pre-side metal in an interconnect;

FIG. 14 is a cross-sectional view taken along the line 14-14 of FIG. 13;

FIG. 15 illustrates the formation of contact metals connecting a second source/drain to a second pre-side metal;

FIG. 16 is a diagram illustrating a method of defining a length of a side metal region of a semiconductor device;

FIG. 17 is a cross-sectional view of a semiconductor device;

FIG. 18 is a cross-sectional view of a semiconductor device; and

FIG. 19 is a cross-sectional view of a semiconductor device.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure. In addition, terms such as first, second, A, B, (a), (b), and the like may be used to describe components of the embodiments. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the embodiments described above and an element having a common function. Unless otherwise mentioned, the descriptions on the embodiments may be applicable to the following embodiments and thus, duplicated descriptions will be omitted for conciseness. As used herein, the terms “substantially”, “approximately”, “generally”, and “about” in reference to a given parameter, property, or condition may include a degree that one of ordinary skill in the art would understand that the given parameter, property, or condition is met (e.g., achieved) with a small degree of variance, such as within acceptable manufacturing tolerances; for example, a parameter that is substantially met may be at least 90% met, at least 95% met, or at least 99% met.

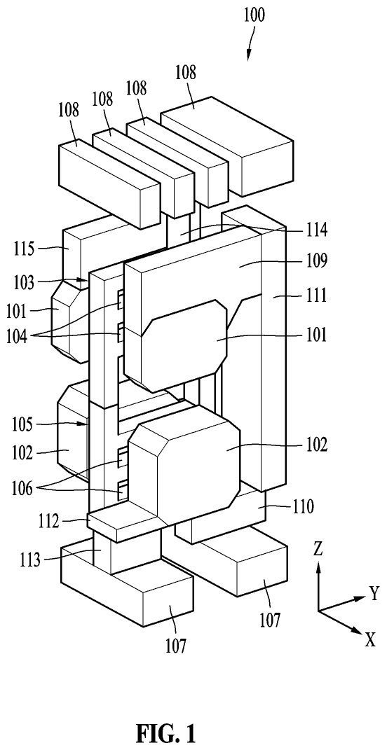

FIG. 1 is a perspective view of a semiconductor device. Referring to FIG. 1, a semiconductor device 100 may include a logic cell used to control the operation of an electronic device (not shown) in which the semiconductor device 100 is used by processing data. For example, the logic cell may include a logic circuit such as an inverter or a flip-flop. The semiconductor device 100 may include a plurality of field effect transistors that are vertically stacked, and may include a plurality of top sources/drains 101 and a plurality of bottom sources/drains 102, which may be epitaxial patterns formed through a selective epitaxial growth (SEG) process.

The semiconductor device 100 may include a top gate electrode 103 between the top sources/drains 101 that are adjacent to each other and a bottom gate electrode 105 between the bottom sources/drains 102 that are adjacent to each other. The top gate electrode 103 and the bottom gate electrode 105 may be separate gate electrodes that are electrically connected to each other. Although not shown in the drawings, an intermediate insulating layer may be disposed between the top gate electrode 103 and the bottom gate electrode 105, according to some embodiments.

The semiconductor device 100 may include a plurality of first nanosheets 104 disposed in the top gate electrode 103 between the top sources/drains 101 that are adjacent to each other and arranged in a direction (e.g., a Z-axis direction) between the plurality of top sources/drains 101 and the plurality of bottom sources/drains 102. The plurality of first nanosheets 104 may also be collectively referred to as first multi-channel bridges (e.g., semiconductor bridges).

The semiconductor device 100 may include a plurality of second nanosheets 106 disposed in the bottom gate electrode 105 between the bottom sources/drains 102 that are adjacent to each other and arranged in the direction (e.g., the Z-axis direction) between the plurality of top sources/drains 101 and the plurality of bottom sources/drains 102. The plurality of second nanosheets 106 may also be collectively referred to as second multi-channel bridges (e.g., semiconductor bridges).

Although not shown in the drawings, the semiconductor device 100 may include a plurality of gate spacers each disposed on both sides (e.g., a side in an +X direction and a side in an −X direction) of the top gate electrode 103 and the bottom gate electrode 105. Each of the gate spacers may cover both sides of each of the top gate electrode 103 and the bottom gate electrode 105.

The semiconductor device 100 may include a rear wiring line 107 and a front wiring line 108. For example, the rear wiring line 107 and the front wiring line 108 may each include at least one of a power line or a signal line. Hereinafter, a case in which the rear wiring line 107 is the power line and the front wiring line 108 is the signal line is described as an example but is not limited thereto. The plurality of power lines 107 may be disposed on the bottom side (e.g., a side in a-Z direction) of the plurality of top sources/drains 101 and the plurality of bottom sources/drains 102, and the plurality of signal lines 108 may be disposed on the top side (e.g., a side in a +Z direction) that is opposite to the bottom side. However, the disposition of the plurality of power lines 107 is not limited to the described embodiments and the plurality of power lines 107 may be disposed on the same side (e.g., the top side) as the plurality of signal lines 108, the plurality of top sources/drains 101, and the plurality of bottom sources/drains 102.

The semiconductor device 100 may include a first contact metal 109 connected to one of the plurality of top sources/drains 101, a second contact metal 110 connected to one of the plurality of power lines 107, and a first via 111 connecting the first contact metal 109 to the second contact metal 110. Although not shown in the drawings, the plurality of top sources/drains 101 may be connected to the plurality of power lines 107 through the first contact metal 109 and the first via 111 without the second contact metal 110.

The semiconductor device 100 may include a third contact metal 112 connected to one of the plurality of bottom sources/drains 102 and a second via 113 connecting another one of the plurality of power lines 107 to the third contact metal 112. Although not shown in the drawings, the semiconductor device 100 may include an additional contact metal between the plurality of power lines 107 and the second via 113.

The semiconductor device 100 may include a third via 114 connecting the top gate electrode 103 to one of the plurality of signal lines 108. Although not shown in the drawings, the third via 114 may be connected to the bottom gate electrode 105.

The semiconductor device 100 may include a fourth contact metal 115 connected to another one of the plurality of top sources/drains 101. Although not shown in the drawings of FIG. 1, the fourth contact metal 115 may be connected to another one of the plurality of signal lines 108, and the semiconductor device 100 may include an additional via connected to the fourth contact metal 115 and another one of the plurality of top sources/drains 101.

Moreover, FIG. 1 illustrates the semiconductor device 100 using an inverter as an example, but the semiconductor device 100 may be implemented as a device such as a NAND or a NOR, and a connection structure and a disposition structure of the plurality of power lines 107, the plurality of contact metals (e.g., the first contact metal 109, the second contact metal 110, the third contact metal 112, and the fourth contact metal 115) connected to the plurality of signal lines 108, and the plurality of vias (e.g., the first via 111, the second via 113, and the third via 114) described above may vary depending on a device to be implemented.

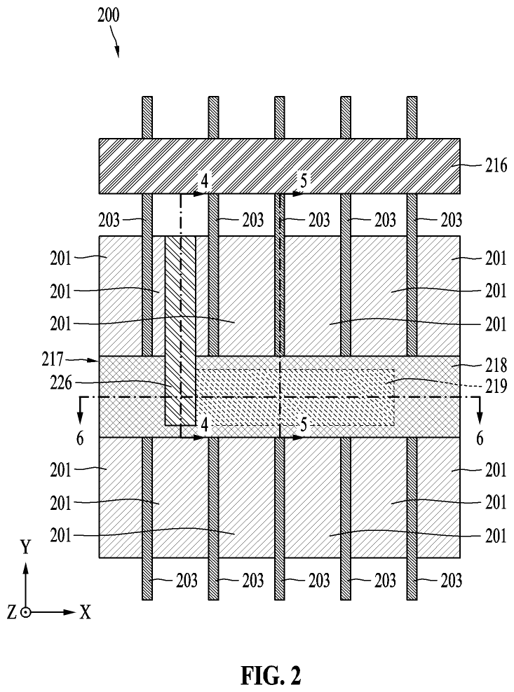

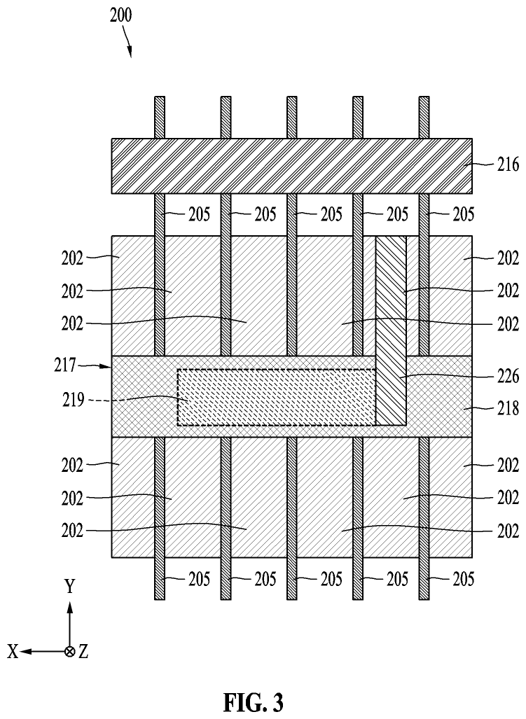

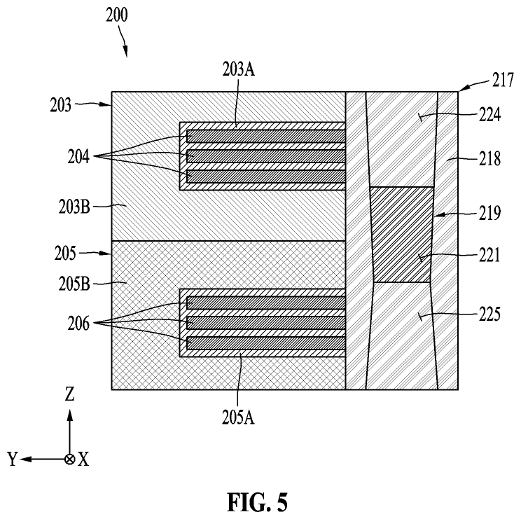

FIG. 2 is a plan view of a semiconductor device. FIG. 3 is a bottom view of a semiconductor device. Referring to FIGS. 2 and 3, a semiconductor device 200 may include a plurality of top sources/drains 201, a plurality of bottom sources/drains 202, a plurality of top gate electrodes 203 each disposed between the top sources/drains 201 that are adjacent to each other, and a plurality of bottom gate electrodes 205 each disposed between the bottom sources/drains 202 that are adjacent to each other. The plurality of top gate electrodes 203 and the plurality of bottom gate electrodes 205 may be partially cut by a gate cut 216. The gate cut 216 may be disposed between a plurality of nanosheets (a plurality of first nanosheets 204 and a plurality of second nanosheets 206 of FIG. 5) of a first stack on one side of the gate cut 216 and a plurality of nanosheets (the plurality of first nanosheets 204 and the plurality of second nanosheets 206 of FIG. 5) of a second stack on another side of the gate cut 216.

The semiconductor device 200 may include an interconnect 217 connecting one of the plurality of top sources/drains 201 to one of the plurality of bottom sources/drains 202. The interconnect 217, which may also be referred to as a “dam,” may be a separate component from the gate cut 216. The interconnect 217 may separate a plurality of nanosheets (the plurality of first nanosheets 204 and the plurality of second nanosheets 206 of FIG. 5) of one stack into two transistors. The interconnect 217 may include an enclosure 218 including an insulating material, such as silicon nitride, and a first side metal 219 disposed inside the enclosure 218. The semiconductor device 200 may secure an increased disposition space of the first side metal 219 connecting the plurality of top sources/drains 201 to the plurality of bottom sources/drains 202 by connecting the plurality of top sources/drains 201 to the plurality of bottom sources/drains 202 through the interconnect 217 rather than the gate cut 216, reduce a space between the gate cut 216 and nanosheets (the plurality of first nanosheets 204 and the plurality of second nanosheets 206 of FIG. 5), reduce the height of the semiconductor device 200 or increase the width of the nanosheets, and reduce or eliminate capacitance between the gate cut 216 and the plurality of top gate electrodes 203 and the plurality of bottom gate electrodes 205.

The semiconductor device 200 may include a first contact metal 226 connecting one of the plurality of top sources/drains 201 to the first side metal 219 and a second contact metal 227 connecting one of the plurality of bottom sources/drains 202 to the first side metal 219.

The first side metal 219 may extend longer than a distance in which the plurality of top gate electrodes 203 is spaced apart from each other or a distance in which the plurality of bottom gate electrodes 205 is spaced apart from each other, in a first direction (e.g., an X-axis direction). For example, in FIG. 2, the first side metal 219 is shown to extend longer than the three top gate electrodes 203 in the first direction (e.g., the X-axis direction), but embodiments are not limited thereto.

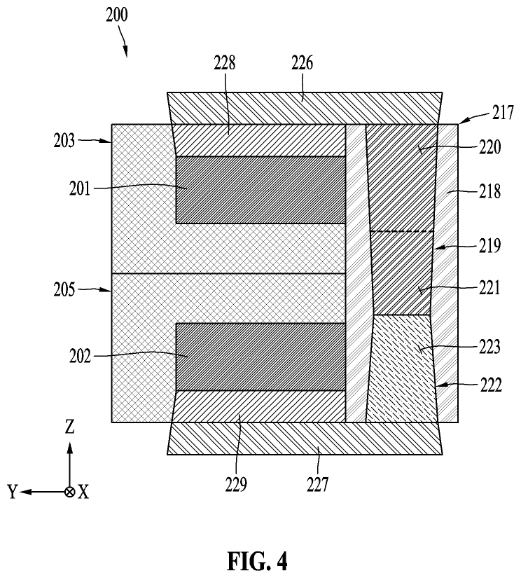

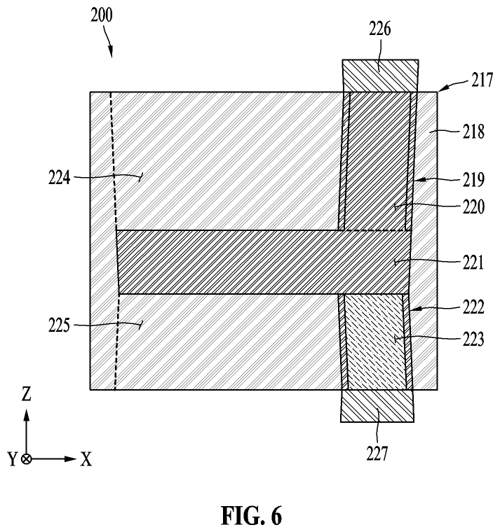

FIG. 4 is a cross-sectional view taken along the line 4-4 of the semiconductor device of FIG. 2. FIG. 5 is a cross-sectional view taken along the line 5-5 of the semiconductor device of FIG. 2. FIG. 6 is a cross-sectional view taken along the line 6-6 of the semiconductor device of FIG. 2.

Referring to FIGS. 2 to 6, the semiconductor device 200 may include the plurality of top sources/drains 201, the plurality of bottom sources/drains 202, the plurality of top gate electrodes 203, the plurality of first nanosheets 204 of the first stack arranged in the height direction (e.g., a Z-axis direction) of the plurality of top gate electrodes 203, the plurality of bottom gate electrodes 205, and the plurality of second nanosheets 206 of the second stack arranged in the height direction (e.g., the Z-axis direction) of the plurality of bottom gate electrodes 205.

The plurality of top gate electrodes 203 may include a first electrode pattern 203A surrounding the plurality of first nanosheets 204. The first electrode pattern 203A may include one of a p-type work function metal or an n-type work function metal. The first electrode pattern 203A may include a metal nitride layer. For example, the first electrode pattern 203A may include at least one of titanium, tantalum, aluminum, tungsten, or molybdenum, or a combination thereof. The first electrode pattern 203A may further include nitrogen. The first electrode pattern 203A may further include carbon.

The plurality of top gate electrodes 203 may include a second electrode pattern 203B surrounding the first electrode pattern 203A. The second electrode pattern 203B may include a metal having resistance that is less than the resistance of the first electrode pattern 203A. For example, the second electrode pattern 203B may include at least one of tungsten, aluminum, titanium, or tantalum, or a combination thereof.

The plurality of bottom gate electrodes 205 may include a third electrode pattern 205A surrounding the plurality of second nanosheets 206. The third electrode pattern 205A may include a material that is different from the first electrode pattern 203A. For example, the first electrode pattern 203A may include one of a p-type work function metal or an n-type work function metal, and the third electrode pattern 205A may include another type of work function metal. The third electrode pattern 205A may include a metal nitride layer. For example, the third electrode pattern 205A may include at least one of titanium, tantalum, aluminum, tungsten, or molybdenum, or a combination thereof. The third electrode pattern 205A may further include nitrogen. The third electrode pattern 205A may further include carbon.

The plurality of bottom gate electrodes 205 may include a fourth electrode pattern 205B surrounding the third electrode pattern 205A. The fourth electrode pattern 205B may include a metal having resistance that is less than the resistance of the third electrode pattern 205A. For example, the fourth electrode pattern 205B may include at least one of tungsten, aluminum, titanium, or tantalum, or a combination thereof.

The plurality of top gate electrodes 203 and the plurality of bottom gate electrodes 205 may be directly connected to each other physically and electrically. Although not shown in the drawings, the semiconductor device 200 may include an intermediate insulating layer between the plurality of top gate electrodes 203 and the plurality of bottom gate electrodes 205, in which the plurality of top gate electrodes 203 and the plurality of bottom gate electrodes 205 may also be electrically connected to each other through a different conductive path.

Although not shown in the drawings, the semiconductor device 200 may include a plurality of gate spacers each disposed on both sides (e.g., a side in an +X direction and a side of an −X direction) of the plurality of top gate electrodes 203 and the plurality of bottom gate electrodes 205. Each of the plurality of gate spacers may cover both sides of the plurality of top gate electrodes 203 and the plurality of bottom gate electrodes 205.

The semiconductor device 200 may include the interconnect 217 electrically connecting the plurality of top sources/drains 201 to the plurality of bottom sources/drains 202. For example, the interconnect 217 is a connection that is also referred to as the “front side to back side routing” and may connect the plurality of top sources/drains 201 to the plurality of bottom sources/drains 202 at the same position along the length (e.g., a dimension in an X direction of FIG. 2) of the interconnect 217.

The interconnect 217 may contact the plurality of first nanosheets 204 and the plurality of second nanosheets 206. The plurality of first nanosheets 204 and the plurality of second nanosheets 206 may not be spaced apart from the interconnect 217. The interconnect 217 may contact a first gate electrode 203 and a second gate electrode 205. The first electrode pattern 203A may not be disposed between the plurality of first nanosheets 204 and the interconnect 217. The second electrode pattern 203B may not be disposed between the plurality of second nanosheets 206 and the interconnect 217.

The interconnect 217 may include the enclosure 218. One surface (e.g., a surface in a +Y direction) of the enclosure 218 may contact the plurality of first nanosheets 204 and the plurality of second nanosheets 206. The enclosure 218 may include an insulating material such as silicon oxide, silicon nitride, silicon oxynitride, silicon oxycarbide, or silicon oxycarbonitride. The interconnect 217 may include the first side metal 219 disposed inside the enclosure 218 and electrically connecting the plurality of top sources/drains 201 to the plurality of bottom sources/drains 202. The first side metal 219 may include a first side via region 220 electrically connected to the plurality of top sources/drains 201 and a side metal region 221 connected to the first side via region 220.

The side metal region 221 may extend lengthwise in the first direction (e.g., an X-axis direction). The length of the side metal region 221 in the first direction (e.g., the X-axis direction) may be greater than the thickness of the side metal region 221 in a third direction (e.g., the Z-axis direction). The side metal region 221 may not extend beyond the plurality of first nanosheets 204 or the plurality of second nanosheets 206 in the height direction of the side metal region 221, which is a direction (e.g., a +/−Z direction) between the plurality of top gate electrodes 203 and the plurality of bottom gate electrodes 205.

The upper surface (e.g., a surface in the +Z direction) of the side metal region 221 may be at a lower level than the lower surface (e.g., a surface in the −Z direction) of the plurality of top sources/drains 201 in the third direction (e.g., the Z-axis direction). The lower surface (e.g., the surface in the −Z direction) of the side metal region 221 may be at a higher level than the upper surface (e.g., the surface in the +Z direction) of the plurality of bottom sources/drains 202 in the third direction (e.g., the Z-axis direction). In another example, the upper surface (e.g., the surface in the +Z direction) of the side metal region 221 may be located between the upper surface (e.g., the surface in the +Z direction) and the lower surface (e.g., the surface in the −Z direction) of the plurality of top sources/drains 201. In addition, the lower surface (e.g., the surface in the −Z direction) of the side metal region 221 may be located between the upper surface (e.g., the surface in the +Z direction) and the lower surface (e.g., the surface in the −Z direction) of the plurality of bottom sources/drains 202.

The upper surface (e.g., the surface in the +Z direction) of the side metal region 221 may be at a lower level in the third direction (e.g., the Z-axis direction) than the lower surface (e.g., the surface in the −Z direction) of the lowermost one of the plurality of first nanosheets 204. The lower surface (e.g., the surface in the −Z direction) of the side metal region 221 may be at a higher level in the third direction (e.g., the Z-axis direction) than the upper surface (e.g., the surface in the +Z direction) of the uppermost one of the plurality of second nanosheets 206. In another example, the upper surface (e.g., the surface in the +Z direction) of the side metal region 221 may be located between the lower surface (e.g., the surface in the −Z direction) of the lowermost one among the plurality of first nanosheets 204 and the upper surface (e.g., the surface in the +Z direction) of the uppermost one of the plurality of first nanosheets 204. In addition, the lower surface (e.g., the surface in the −Z direction) of the side metal region 221 may be located between the lower surface (e.g., the surface in the −Z direction) of the lowermost one of the plurality of second nanosheets 206 and the upper surface (e.g., the surface in the +Z direction) of the uppermost one of the plurality of second nanosheets 206. The upper surface (e.g., the surface in the +Z direction) of the side metal region 221 may refer to a boundary between the side metal region 221 and a first side metal recess 224. The lower surface (e.g., the surface in the −Z direction) of the side metal region 221 may refer to a boundary between the side metal region 221 and a second side metal recess 225.

The first side via region 220 and the side metal region 221 may have a width that decreases in a direction (e.g., the −Z direction) from the plurality of top gate electrodes 203 toward the plurality of bottom gate electrodes 205. In one cross-section (e.g., an XZ plane of FIG. 6) of the interconnect 217, which is a plane that is substantially orthogonal to the plurality of top gate electrodes 203 and the plurality of bottom gate electrodes 205, an inclination of one side (e.g., the side in the +X direction) of the first side via region 220 may be substantially the same as an inclination of one side (e.g., the side in the +X direction) of the side metal region 221.

The interconnect 217 may include a second side metal 222 disposed inside the enclosure 218 and electrically connecting the plurality of top sources/drains 201 to the plurality of bottom sources/drains 202. The second side metal 222 may be physically and electrically connected to the first side metal 219. The second side metal 222 may include a second side via region 223 electrically connected to the side metal region 221 and the plurality of bottom sources/drains 202.

The second side via region 223 may have a width that decreases in a direction (e.g., the +Z direction) from the plurality of bottom gate electrodes 205 toward the plurality of top gate electrodes 203. The second side via region 223 may overlap the first side via region 220 in the third direction (e.g., the Z-axis direction). The interconnect 217 may include the first side metal recess 224 formed by recessing a portion of the first side metal 219. The first side via region 220 and the first side metal recess 224 may be positioned along the side metal region 221. The first side metal recess 224 may contact the first side via region 220 and the side metal region 221. The inclination of one side (e.g., the side in the +X direction of FIG. 6) of the first side via region 220 may be different from an inclination of one side (e.g., the side in the +X direction of FIG. 6) of the first side metal recess 224. The inclination of another side (e.g., the side in the −X direction of FIG. 6) of the first side via region 220 may be substantially the same as the inclination of one side (e.g., the side in the +X direction of FIG. 6) of the first side metal recess 224.

The interconnect 217 may include the second side metal recess 225 formed by recessing a portion of the second side metal 222. The second side via region 223 and the second side metal recess 225 may be positioned along the side metal region 221. The first side metal recess 224 and the second side metal recess 225 may be positioned opposite to each other with respect to the side metal region 221. The second side metal recess 225 may contact the second side via region 223 and the side metal region 221. An inclination of one side (e.g., the side in the +X-direction of FIG. 6) of the second side via region 223 may be different from an inclination of one side (e.g., the side in the +X direction of FIG. 6) of the second side metal recess 225. The inclination of another side (e.g., the side in the −X direction of FIG. 6) of the second side via region 223 may be substantially the same as the inclination of one side (e.g., the side in the +X direction of FIG. 6) of the second side metal recess 225.

The first side metal recess 224 and the second side metal recess 225 may be filled with an insulating material. The insulating material included in the first side metal recess 224 and the second side metal recess 225 may include at least one of silicon oxide, silicon nitride, silicon oxynitride, silicon oxycarbide, or silicon oxycarbonitride, or a combination thereof. The first side metal recess 224 and the second side metal recess 225 may include the same material as the enclosure 218. In another example, the first side metal recess 224 and the second side metal recess 225 may include a different material from the enclosure 218.

The first side metal 219 and the second side metal 222 may include any suitable metallic material. In an example, the first side metal 219 and the second side metal 222 may include at least one of tungsten (W), cobalt (Co), molybdenum (Mo), or ruthenium (Ru), or a combination thereof. In another example, the first side metal 219 and the second side metal 222 may include titanium (Ti) and/or titanium nitride (TIN). The first side metal 219 and the second side metal 222 may include the same material but are not limited thereto. In another example, the first side metal 219 and the second side metal 222 may include different materials. In an embodiment not shown, the first side via region 220, the side metal region 221, and the second side via region 223 may be defined by a single side metal.

The semiconductor device 200 may include the first contact metal 226 and the second contact metal 227. The first contact metal 226 may be connected to the first side via region 220. The second contact metal 227 may be connected to the second side via region 223. The semiconductor device 200 may include a third contact metal 228 connecting the first contact metal 226 to the plurality of top sources/drains 201. The semiconductor device 200 may include a fourth contact metal 229 connecting the second contact metal 227 to the plurality of bottom sources/drains 202.

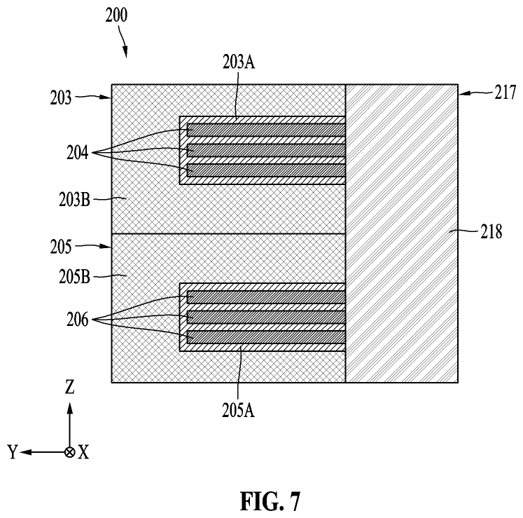

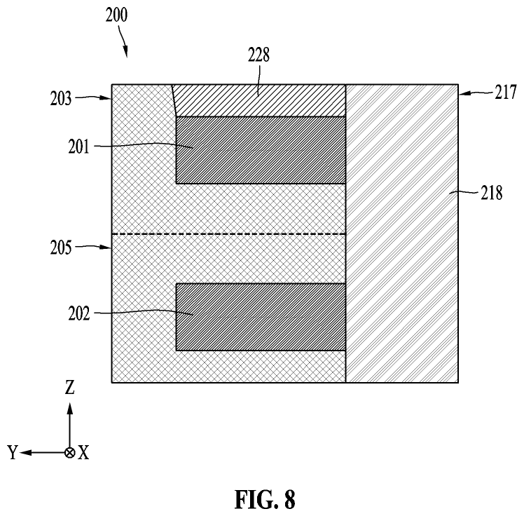

FIGS. 7 to 15 are diagrams illustrating a method of manufacturing a semiconductor device. In particular, FIG. 7 illustrates the formation of a first gate electrode, a second gate electrode, and an interconnect such that a plurality of first nanosheets and a plurality of second nanosheets contact the interconnect. Referring to FIG. 7, a method of manufacturing the semiconductor device 200 may include forming the interconnect 217 including the plurality of top sources/drains 201 (see FIG. 8), the plurality of bottom sources/drains 202 (see FIG. 8), the plurality of top gate electrodes 203 disposed between the top sources/drains 201 that are adjacent to each other and including the first electrode pattern 203A and the second electrode pattern 203B, the plurality of first nanosheets 204, the plurality of bottom gate electrodes 205 disposed between the bottom sources/drains 202 that are adjacent to each other and including the third electrode pattern 205A and the fourth electrode pattern 205B, the plurality of second nanosheets 206, and the enclosure 218 in contact with the plurality of first nanosheets 204 and the plurality of second nanosheets 206.

FIG. 8 illustrates the formation of a contact metal connected to a first source/drain. Referring to FIG. 8, a method of manufacturing the semiconductor device 200 may include forming a contact metal 228 (referred to as the “third contact metal 228” of FIGS. 4 to 6) in the plurality of top sources/drains 201.

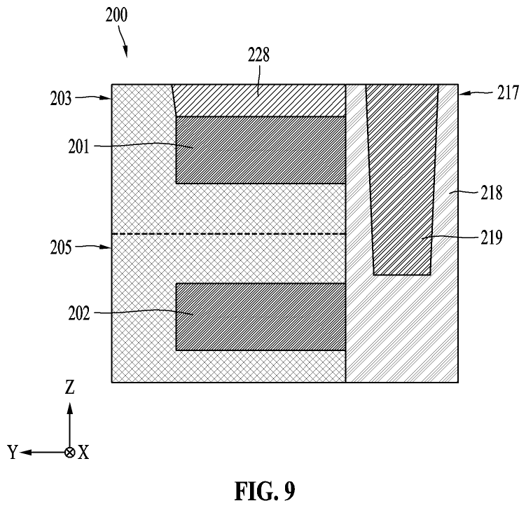

FIG. 9 illustrates the formation of a first pre-side metal in an interconnect. Referring to FIG. 9, a method of manufacturing the semiconductor device 200 may include, after the inside of the enclosure 218 is etched, forming a first pre-side metal 219 by applying a conductive material to the etched region. The first pre-side metal 219 may extend lengthwise in a first direction (e.g., an X-axis direction).

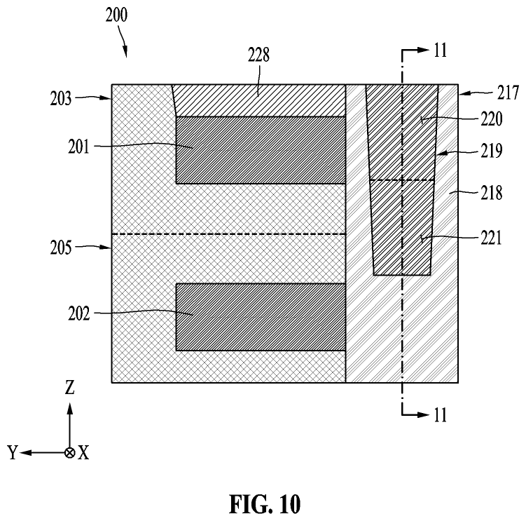

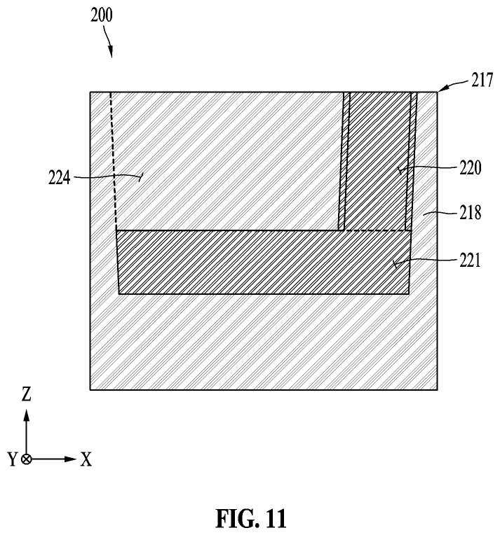

FIG. 10 illustrates the formation of a first side via region and a side metal region from a first pre-side metal in an interconnect. FIG. 11 is a cross-sectional view taken along the line 11-11 of FIG. 10. Referring to FIGS. 10 and 11, a method of manufacturing the semiconductor device 200 may include forming the first side via region 220 to be electrically connected to the plurality of top sources/drains 201 and the side metal region 221 connected to the first side via region 220 by forming the first side metal recess 224 by recessing a portion of the first pre-side metal 219.

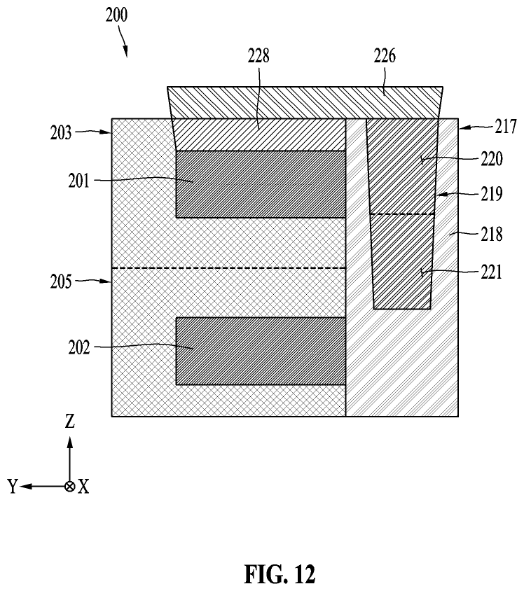

FIG. 12 illustrates the formation of a contact metal connecting a first pre-side metal to a first source/drain. Referring to FIG. 12, a method of manufacturing the semiconductor device 200 may include forming a contact metal 226 (referred to as the “first contact metal 226” of FIGS. 2 to 6) connecting the contact metal 228 to the first side via region 220.

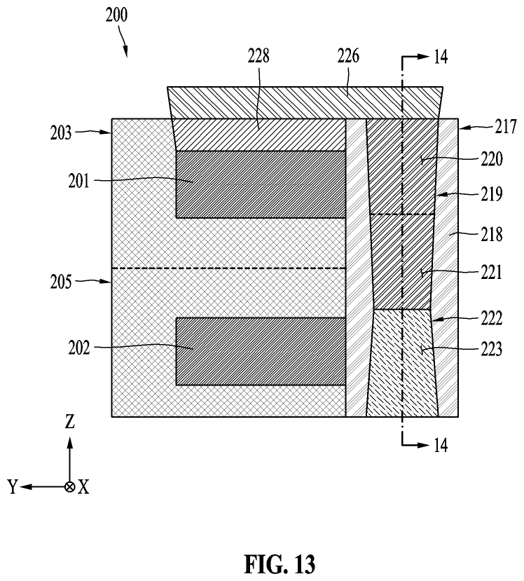

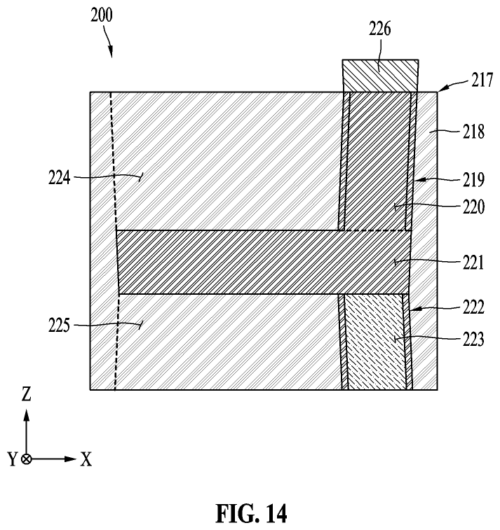

FIG. 13 illustrates the formation of a second pre-side metal in an interconnect. FIG. 14 is a cross-sectional view taken along the line 14-14 of FIG. 13. Referring to FIGS. 13 and 14, a method of manufacturing the semiconductor device 200 may include forming the second side metal 222 connected to the first side metal 219 inside the enclosure 218. The method may include forming the second side via region 223 to be electrically connected to the plurality of bottom sources/drains 202 by forming the second side metal recess 225 by recessing a portion of the second side metal 222. In an embodiment not shown, the second side via region 223 may be formed as a side via in a hole type.

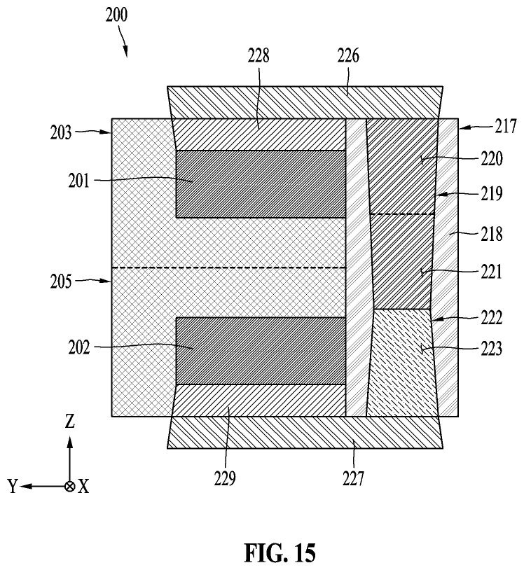

FIG. 15 illustrates the formation of contact metals connecting a second source/drain to a second pre-side metal. Referring to FIG. 15, a method of manufacturing the semiconductor device 200 may include forming a contact metal 229 (referred to as the “fourth contact metal 229” of FIGS. 4 to 6) electrically connected to the plurality of bottom sources/drains 202 and a contact metal 227 (referred to as the “second contact metal 227” of FIGS. 4 to 6) electrically connected to the second side via region 223. The contact metals 227 and 229 may be electrically connected to each other.

Although not shown in the drawings, when the plurality of top sources/drains 201 is connected to each other (in the case of the “front side to front side routing”), the second side metal 222, the second side metal recess 225, and the contact metals 227 and 229 may not be formed. Although not shown in the drawings, when the plurality of bottom sources/drains 202 is connected to each other (in the case of the “back side to back side routing”), the first side metal 219, the first side metal recess 224, and the contact metals 226 and 228 may not be formed, and the second side metal 222 may be defined by the second side via region 223 and the side metal region 221.

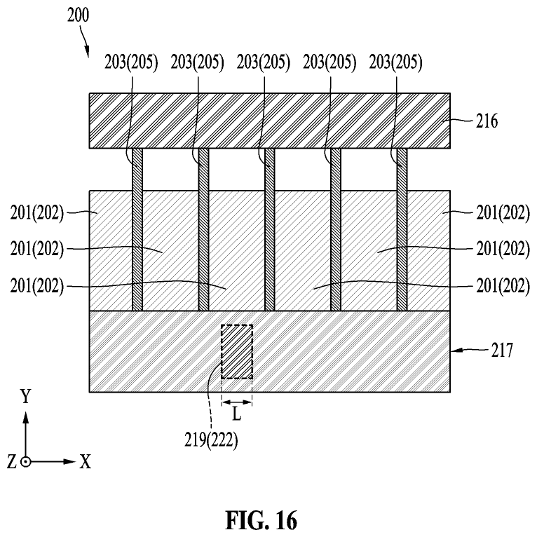

FIG. 16 is a diagram illustrating a method of defining a length of a side metal region of a semiconductor device. Referring to FIG. 16, the semiconductor device 200 may include the plurality of top sources/drains 201, the plurality of bottom sources/drains 202, the plurality of top gate electrodes 203, the plurality of bottom gate electrodes 205, the gate cut 216, and the interconnect 217. The minimum cut length L of the length of the first side metal 219 and/or the second side metal 222 disposed in the interconnect 217 may be defined as substantially the same as or less than a distance between the top gate electrodes 203 that are adjacent to each other and/or a distance between the bottom gate electrodes 205 that are adjacent to each other.

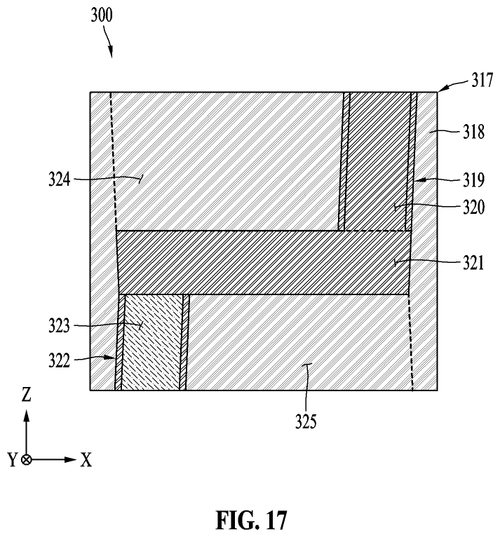

FIG. 17 is a cross-sectional view of a semiconductor device. Referring to FIG. 17, a semiconductor device 300 may have a structure (the “front side to back side routing”) connecting top sources/drains (e.g., the plurality of top sources/drains 201 of FIG. 2) at a first position along the length (e.g., a dimension in an X direction) of an interconnect 317 to bottom sources/drains (e.g., the plurality of bottom sources/drains 202 of FIG. 3) at a second position that is different from the first position along the length of the interconnect 317.

The semiconductor device 300 may include the interconnect 317. The interconnect 317 may include an enclosure 318. The interconnect 317 may include a first side metal 319 and/or a second side metal 322. The first side metal 319 may include a first side via region 320 and a side metal region 321. The second side metal 322 may include a second side via region 323. The interconnect 317 may include a first side metal recess 324 and a second side metal recess 325. The first side metal recess 324 and the first side via region 320 may be sequentially arranged along the longitudinal direction (e.g., the X direction) of the interconnect 317, and the second side via region 323 and the second side metal recesses 325 may be sequentially arranged along the longitudinal direction (e.g., the X direction) of the interconnect 317.

Although not shown in the drawings, the interconnect 317 may include a single side metal defined by the first side via region 320, the side metal region 321, and the second side via region 323. And, when viewed in the height direction (e.g., a Z direction) of the interconnect 317, the first side via region 320 may partially overlap the second side via region 323.

A position of the first side via region 320 along the length (e.g., the dimension in the X direction) of the interconnect 317 may be different from a position of the second side via region 323. When viewed in the height direction (e.g., the Z direction) of the interconnect 317, the first side via region 320 may not overlap the second side via region 323. Although not shown in the drawings, when viewed in the height direction (e.g., the Z direction) of the interconnect 317, the first side via region 320 may partially overlap the second side via region 323.

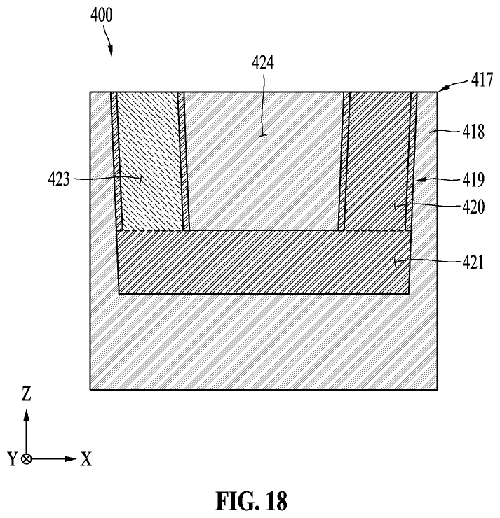

FIG. 18 is a cross-sectional view of a semiconductor device. Referring to FIG. 18, a semiconductor device 400 may have a structure (the “front side to front side routing”) connecting a first top source/drain (e.g., the plurality of top sources/drains 201 of FIG. 2) at a first position along the length (e.g., a dimension in an X direction) of an interconnect 417 to a second top source/drain (e.g., the plurality of top sources/drains 201 of FIG. 2) at a second position that is different from the first position along the length of the interconnect 417.

The semiconductor device 400 may include the interconnect 417. The interconnect 417 may include an enclosure 418. The interconnect 417 may include a side metal 419. The side metal 419 may include a first side via region 420, a side metal region 421, and a second side via region 423. The first side via region 420 and the second side via region 423 may be at substantially the same position when viewed along the height (e.g., the dimension in a Z direction) of the interconnect 417. The interconnect 417 may include the first side via region 420 and a side metal recess 424 in contact with the side metal region 421 and the second side via region 423.

An inclination of a first side (e.g., a side in an +X direction) of the side metal recess 424 may be substantially the same as an inclination of the first side (e.g., the side in the +X direction) of the first side via region 420. The inclination of the first side (e.g., the side in the +X direction) of the side metal recess 424 may be different from the inclination of the first side (e.g., the side in the +X direction) of the first side via region 420. The inclination of the first side (e.g., the side in the +X direction) of the side metal recess 424 may be substantially the same as an inclination of a second side (e.g., a side in an −X direction) that is opposite to the first side of the first side via region 420.

The inclination of the second side (e.g., the side in the −X direction) that is opposite to the first side of the side metal recess 424 may be substantially the same as an inclination of the first side (e.g., the side in the +X direction) of the second side via region 423. The inclination of the second side of the side metal recess 424 may be different from the inclination of the second side (e.g., the side in the −X direction) that is opposite to the first side of the second side via region 423. The inclination of the second side of the side metal recess 424 may be substantially the same as the inclination of the second side (e.g., the side in the −X direction) that is opposite to the first side of the second side via region 423.

Although not shown in the drawings, the interconnect 417 may include a first side metal 419 including the first side via region 420 and the side metal region 421, and a second side metal including the second side via region 423. And, the interconnect 417 may include the first side metal 419 including the first side via region 420, and the second side metal including the side metal region 421 and the second side via region 423. Moreover, the interconnect 417 may include the first side metal 419 including the first side via region 420, the second side metal including the side metal region 421, and a third side metal including the second side via region 423.

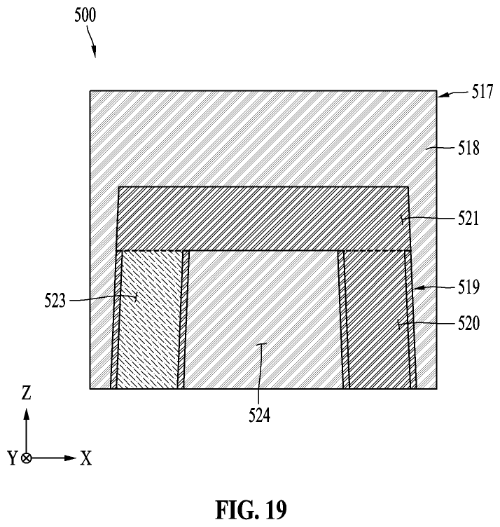

FIG. 19 is a cross-sectional view of a semiconductor device. Referring to FIG. 19, a semiconductor device 500 may have a structure (the “back side to back side routing”) connecting a first bottom source/drain (e.g., the plurality of bottom sources/drains 202 of FIG. 3) at a first position along the length (e.g., a dimension in an X direction) of an interconnect 517 to a second bottom source/drain (e.g., the plurality of bottom sources/drains 202 of FIG. 3) at a second position that is different from the first position along the length of the interconnect 517.

The semiconductor device 500 may include the interconnect 517. The interconnect 517 may include an enclosure 518. The interconnect 517 may include a side metal 519. The side metal 519 may include a first side via region 520, a side metal region 521, and a second side via region 523. The first side via region 520 and the second side via region 523 may be at substantially the same position when viewed along the height (e.g., a dimension in a Z direction) of the interconnect 517. The interconnect 517 may include the first side via region 520 and a side metal recess 524 in contact with the side metal region 521 and the second side via region 523.

An inclination of a first side (e.g., a side in an +X direction) of the side metal recess 524 may be substantially the same as an inclination of the first side (e.g., the side in the +X direction) of the first side via region 520. The inclination of the first side (e.g., the side in the +X direction) of the side metal recess 524 may be different from the inclination of the first side (e.g., the side in the +X direction) of the first side via region 520. The inclination of the first side (e.g., the side in the +X direction) of the side metal recess 524 may be substantially the same as the inclination of a second side (e.g., a side in an −X direction) that is opposite to the first side of the first side via region 520.

The inclination of the second side (e.g., the side in the −X direction) that is opposite to the first side of the side metal recess 524 may be substantially the same as an inclination of the first side (e.g., the side in the +X direction) of the second side via region 523. The inclination of the second side of the side metal recess 524 may be different from the inclination of the second side (e.g., the side in the −X direction) that is opposite to the first side of the second side via region 523. The inclination of the second side of the side metal recess 524 may be substantially the same as the inclination of the second side (e.g., the side in the −X direction) that is opposite to the first side of the second side via region 523.

Although not shown in the drawings, the interconnect 517 may include the side metal 519, which includes the first side via region 520 and the side metal region 521, and a second side metal, which includes the second side via region 523. And, the interconnect 517 may include the side metal 519, which includes the first side via region 520, and the second side metal, which includes the side metal region 521 and the second side via region 523. Moreover, the interconnect 517 may include the side metal 519 including the first side via region 520, the second side metal including the side metal region 521, and a third side metal including the second side via region 523.

As described above, the semiconductor device may have various routing structures, such as a front-side to front-side routing structure, a front-side to back-side routing structure, or a back-side to back-side routing structure, through a separate interconnect from a gate cut. For example, the semiconductor device may implement various routing structures such as a structure connecting adjacent top sources/drains to each other among a plurality of top sources/drains, a structure connecting not adjacent top sources/drains to each other among the plurality of top sources/drains, a structure connecting adjacent bottom sources/drains to each other among a plurality of bottom sources/drains, a structure connecting not adjacent bottom sources/drains to each other among the plurality of bottom sources/drains, a structure connecting one of the plurality of top sources/drains to one of the plurality of bottom sources/drains, or a structure connecting top sources/drains and/or bottom sources/drains on one side to top sources/drains and/or bottom sources/drains on another side, based on an interconnect.

Although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and/or equivalents of the claims are within the scope of the following claims.

What is claimed is:

1. A semiconductor device, comprising:
a first source/drain;
a second source/drain;
a first nanosheet;
a second nanosheet; and
an interconnect configured to electrically connect the first source/drain to the second source/drain, and contacting the first and second nanosheets, said interconnect including:
an enclosure;
a first side via region extending inside the enclosure and electrically connected to the first source/drain;
a second side via region extending inside the enclosure and electrically connected to the second source/drain; and
a side metal region extending inside the enclosure and electrically connected to the first side via region and the second side via region.

2. The device of claim 1, wherein the interconnect is configured to separate the first nanosheet from the second nanosheet.

3. The device of claim 1, wherein the side metal region does not extend beyond the first nanosheet or the second nanosheet in a height direction of the side metal region.

4. The device of claim 3, wherein an inclination of at least one of the first side via region and the second side via region is substantially the same as an inclination of the side metal region, in a cross-section of the interconnect.

5. The device of claim 1, wherein the interconnect further includes a first side metal recess in contact with the first side via region and the side metal region.

6. The device of claim 5, wherein the first side via region and the first side metal recess are arranged along the side metal region.

7. The device of claim 5, wherein an inclination of the first side via region is substantially the same as an inclination of the first side metal recess, in a cross-section of the interconnect.

8. The device of claim 5, wherein an inclination of the first side via region is different from an inclination of the first side metal recess, in a cross-section of the interconnect.

9. The device of claim 5, wherein the interconnect further includes a second side metal recess in contact with the second side via region and the side metal region.

10. The device of claim 1, further comprising:
a plurality of first nanosheets and a plurality of second nanosheets; and\
wherein the side metal region has a minimum cutting length that is substantially the same as or less than a distance between adjacent first nanosheets among the plurality of first nanosheets or a distance between adjacent second nanosheets among the plurality of second nanosheets.

11. A method of manufacturing a semiconductor device, comprising:
forming a first source/drain, a second source/drain, an interconnect comprising an enclosure, and a first nanosheet and a second nanosheet in contact with the enclosure, said forming the interconnect including forming a side metal region as at least a portion of a side metal extending inside the enclosure.

12. The method of claim 11, wherein said forming the interconnect includes:
forming at least one side via region of a first side via region electrically connected to the first source/drain, or a second side via region electrically connected to the second source/drain, by recessing a portion of the side metal.

13. The method of claim 12, further comprising:
forming a first contact metal that electrically connects the first source/drain to the first side via region.

14. The method of claim 12, further comprising:
forming a second contact metal that electrically connects the second source/drain to the second side via region.

15. The method of claim 12, wherein an inclination of the first side via region or the second side via region is substantially the same as an inclination of the side metal region, in a cross-section of the interconnect.

16. The method of claim 12, wherein an inclination of a side metal recess formed by recessing a portion of the side metal is substantially the same as an inclination of the first side via region or the second side via region, in a cross-section of the interconnect.

17. The method of claim 12, wherein an inclination of a side metal recess formed by recessing a portion of the side metal is different from an inclination of the first side via region or the second side via region, in one cross-section of the interconnect.

18. The method of claim 11, wherein said forming the side metal region includes cutting, as a unit, a metal having a minimum cutting length that is substantially the same as or less than a distance between adjacent first nanosheets or a distance between adjacent second nanosheets.

19. The method of claim 11, further comprising:
forming a first contact metal electrically connected to the first source/drain.

20. The method of claim 19, further comprising:
forming a second contact metal electrically connected to the second source/drain.
